(19) United States
(12) Patent Application Publication
(10) Pub. No.: US 2017/0084650 A1
(43) Pub. Date: Mar. 23, 2017

(54) COLOR FILTER SENSORS

(71) Applicant: QUALCOMM Incorporated, San Diego, CA (US)

(72) Inventors: Sergiu Radu Goma, San Diego, CA (US); Kalin Mitkov Atanassov, San Diego, CA (US); Hasib Ahmed Siddiqui, San Diego, CA (US); Biay-Cheng Hseih, Irvine, CA (US); Todor Georgiev Georgiev, Sunnyvale, CA (US)

(21) Appl. No.: 14/861,678

(22) Filed: Sep. 22, 2015

(51) Int. Cl. H01L 27/146

(52) U.S. Cl. CPC H01L 27/14621; H01L 27/14645

(57) ABSTRACT

Innovations include a sensing device having a sensor array comprising a plurality of sensors, each sensor having a length dimension and a width dimension and configured to generate a signal responsive to radiation incident on the sensor, and a filter array comprising a plurality of filters, the filter array disposed to filter light before it is incident on the sensor array, the filter array arranged relative to the sensor array so each of the plurality of sensors receives radiation propagating through at least one corresponding filter. Each filter has a length dimension and a width dimension, and a ratio of the length dimension of a filter to the length dimension of a corresponding sensor, a ratio of the width dimension of a filter to the width dimension of a corresponding sensor, or both, is a non-integer greater than 1.

### BACKGROUND OF THE INVENTION

Field of the Disclosure

The present application relates generally to color filter arrays (CFAs) for digital imaging.

Description of the Related Art

Image sensors, including complementary metal oxide semiconductor (CMOS) image sensors and charge-coupled devices (CCDs), may be used in digital imaging applications to capture scenes. An image sensor includes an array of sensors. Each sensor in the array includes at least a photosensitive element for outputting a signal having a magnitude proportional to the intensity of incident light or radiation contacting the photosensitive element. When exposed to incident light reflected or emitted from a scene, each sensor in the array outputs a signal having a magnitude corresponding to an intensity of light at one point in the scene. The signals output from each photosensitive element may be processed to form an image representing the captured scene.

To capture color images, photo sensitive elements should be able to separately detect wavelengths of light associated with different colors. For example, a sensor may be designed to detect first, second, and third colors (e.g., red, green and blue wavelengths). To accomplish this, each sensor in the array of sensors may be covered with a single color filter (e.g., a red, green or blue filter). The single color filters may be arranged into a pattern to form a color filter array (CFA) over the array of sensors such that each individual filter in the CFA is aligned with one individual sensor in the array. Accordingly, each sensor in the array may detect the single color of light corresponding to the filter aligned with it.

One example of a CFA pattern is the Bayer CFA, where the array portion consists of rows of alternating red and green color filters and alternating blue and green color filters. Each color filter corresponds to one sensor in an underlying sensor array. In a Bayer CFA, half of the color filters are green color filters, one quarter of the color filters are blue color filters, and one quarter of the color filters are red color filters. The use of twice as many green filters as red and blue filters, respectively, imitates the human eye's greater ability to see green light than red and blue light. In some arrangement, each sensor in the Bayer CFA is sensitive to a different color of light than its closest neighbors disposed in a horizontal and vertical arrangement in the array. For example, the nearest neighbors to each green filter are red and blue filters, the nearest neighbors to each red filter are green filters, and the nearest neighbor to each blue filter are green filters. Because each filter's closest neighbors have different color designations than it, each filter overlies only one corresponding sensor.

Color filter material consists of dyes, or more commonly pigments, to define the spectrum of the color filter. The size of each color filter correspond to the size of the sensor, for example, a 1:1 ratio. However, the manufacturing difficulties and physical limitations in achieving this level of spatial resolution have become impractical for sensors smaller than 1.1 μm resolution. Currently, technology trends demand higher image resolution, and hence, smaller sensor size; however, technology cannot reliably reduce pigmentation and dye color filter sizes below 1.1 μm. It is also more difficult to align the filter elements with their corresponding sensors. Accordingly, new approaches to using CFA's may improve implementations that use sub-micron-sized color image sensors.

### SUMMARY

The systems, methods, and devices of the invention each have several aspects, no single one of which is solely responsible for its desirable attributes. Without limiting the scope of this invention as expressed by the claims which follow, some features will now be discussed briefly. After considering this discussion, and particularly after reading the section entitled “Detailed Description” one will understand how the features of this invention provide advantages.

One innovation includes a sensing device including a sensor array comprising a plurality of sensors, each sensor having a length dimension and a width dimension and configured to generate a signal responsive to radiation incident on the sensor, and a filter array comprising a plurality of filters, the filter array disposed to filter light before it is incident on the sensor array, the filter array arranged relative to the sensor array so each of the plurality of sensors receives radiation propagating through at least one corresponding filter, each filter having a length dimension and a width dimension, where a ratio of the length dimension of a filter to the length dimension of a corresponding sensor, a ratio of the width dimension of a filter to the width dimension of a corresponding sensor, or both, is a non-integer greater than 1.

Such an innovation may include other aspects. For example, the filter array may include a repeated arrangement of filters, the repeated arrangement including a first filter having a first length and width dimension, configured to pass a first range of wavelengths, a second filter having a second length and width dimension, configured to pass a second range of wavelengths, a third filter having a third length and width dimension, configured to pass a third range of wavelengths, and a fourth filter having a fourth length and width dimension, configured to pass any of the first, second, or third ranges of wavelengths. In one aspect, the repeated arrangement of filters are arranged so that the first filter is disposed over a first sensor and over at least a portion of at least three other sensors adjacent to the first sensor. In another aspect, the ratio of the length dimension of a filter to the length dimension of a corresponding sensor is a non-integer greater than 1. In another aspect, a ratio of the width dimension of a filter to the width dimension of a corresponding sensor is a non-integer greater than 1. In another aspect, at least some of the plurality of sensors are positioned relative to the filter elements to receive radiation filtered by no more than two of the first, second, third and fourth filters. In another aspect, the length dimensions of the first filter, the second filter, the third filter, and the fourth filter are equal. In another aspect, the width dimensions of the first filter, the second filter, the third filter, and the fourth filter are equal. In another aspect, the first filter passes light wavelengths in a range of about 570 nm to about 750 nm, the second filter passes light wavelengths in a range of about 450 nm to about 590 nm, and the third filter passes light wavelengths in a range of about 380 nm to about 570 nm. In another aspect, the filter array comprises a polymeric material. In another aspect, each of the plurality of sensors comprises a light receiving surface that defined by an area dimension that is substantially the same size. In another aspect, the sensing device may be configured wherein a distance from a center of one sensor to a center of an adjacent sensor is less than 1.1 μm. In another aspect, the ratio of the length dimension of a filter and the length dimension of a corresponding sensor is between 1.0 and 2.0. In another aspect, the ratio of the width dimension of a filter and the width dimension of a corresponding sensor is between 1.0 and 2.0.

Another innovation includes a method, including filtering light propagating towards a sensor array with a filter array comprising a plurality of filters, the filter array positioned relative to the sensor array to filter the light before it is incident on the sensor array, each filter having a length dimension and a width dimension, receiving the filtered light on the sensor array, the sensor array comprising a plurality of sensors each configured to generate a signal responsive to light incident on the sensor, the sensor array arranged relative to the filter array so each of the plurality of sensors receives light propagating through at least one filter corresponding to the sensor, each sensor having a length dimension and a width dimension, wherein a ratio of the length dimension of a filter to the length dimension of a corresponding sensor, a ratio of the width dimension of a filter to the width dimension of a corresponding sensor, or both, is a non-integer greater than 1.

Such an innovation may include other aspects. For example, in one aspect the filter array comprises a repeated arrangement of filters, the repeated arrangement including a first filter having a first length and width dimension, configured to pass a first range of wavelengths, a second filter having a second length and width dimension, configured to pass a second range of wavelengths, a third filter having a third length and width dimension, configured to pass a third range of wavelengths, and a fourth filter having a fourth length and width dimension, configured to pass any of the first, second, or third ranges of wavelengths. In some aspects, the repeated arrangement of filters are arranged so that the first filter is disposed over a first sensor and over at least a portion of at least three other sensors adjacent to the first sensor. In another aspect, the ratio of the length dimension of a filter to the length dimension of a corresponding sensor is a non-integer greater than 1. In another aspect, a ratio of the width dimension of a filter to the width dimension of a corresponding sensor is a non-integer greater than 1. In another aspect, the first filter passes light wavelengths in a range of about 570 nm to about 750 nm, the second filter passes light wavelengths in a range of about 450 nm to about 590 nm, and the third filter passes light wavelengths in a range of about 380 nm to about 570 nm.

In another innovation, a sensing device includes a sensor array comprising a plurality of sensors, each sensor having a length dimension and a width dimension, and means for filtering light propagating towards the sensor array, each of the means for filtering light positioned relative to the sensor array to filter the light before it is incident on one or more corresponding sensors, the means for filtering light each having a length dimension and a width dimension. In such innovations, a ratio of the length dimension of each of the means for filtering light to the length dimension of a corresponding sensor, a ratio of the width dimension of each means for filtering light to the width dimension of a corresponding sensor, or both, is a non-integer greater than 1.

Such an innovation may include other aspects. For example, in an aspect the means for filtering light of sensing device comprises an array of filters. In another aspect the means for filtering light comprises a repeated arrangement of filters, the repeated arrangement including a first filter having a first length dimension and a first width dimension, configured to pass a first range of wavelengths, a second filter having a second length dimension and a second width dimension, configured to pass a second range of wavelengths, a third filter having a third length dimension and a third width dimension, configured to pass a third range of wavelengths, and a fourth filter having a fourth length dimension and a fourth width dimension, configured to pass any of the first range of wavelengths, the second range of wavelengths, or the third range of wavelengths. In another aspect, the repeated arrangement of filters are arranged so that the first filter is disposed over a first sensor and over at least a portion of at least three other sensors adjacent to the first sensor. In another aspect, at least some of the plurality of sensors are positioned relative to the filter elements to receive radiation filtered by no more than two of the first, second, third and fourth filters. In another aspect, the length dimensions of the first filter, the second filter, the third filter, and the fourth filter are equal. In another aspect, the width dimensions of the first filter, the second filter, the third filter, and the fourth filter are equal. In another aspect, the first filter passes light wavelengths in a range of about 570 nm to about 750 nm, the second filter passes light wavelengths in a range of about 450 nm to about 590 nm, and the third filter passes light wavelengths in a range of about 380 nm to about 570 nm. In another aspect, the ratio of the length dimension of a means for filtering light and the length dimension of a corresponding sensor is between 1.0 and 2.0. In another aspect, ratio of the width dimension of a means for filtering light and the width dimension of a corresponding sensor is between 1.0 and 2.0.

Another innovation includes an apparatus including a sensor array comprising a plurality of sensors, each of the plurality of sensors having a length dimension and a width dimension, and a filter array comprising a plurality of filters, the filter array disposed adjacent to the sensor array such that light passing through the filter array is incident on the sensor array, each of the plurality of filters having a length dimension and a width dimension, where at least one of the filter length and width dimensions are sized relative to the sensor length and width dimensions, respectively, such that the filters have at least one of a filter length dimension greater than the sensor length dimension and less than twice the sensor length dimension, and a filter width dimension greater than the sensor width dimension and less than twice the sensor width dimension.

Another innovation includes a method of manufacturing a sensing device, including providing an array of sensors, each sensor element having a surface for receiving radiation, the surface defined by a length dimension and width dimension, and each sensor element being configured to generate a signal based on radiation that is incident on the sensor element; and arranging an array of filter elements adjacent to the array of sensors to filter radiation propagating towards the surfaces of the sensors in the array of sensors, each filter element having a length dimension and a width dimension, at least one of the length dimension and the width dimension of the filter element being sized to be larger than a respective length dimension and width dimension of a corresponding sensor element which receives radiation that has passed through each filter element, each filter element being sized such that a result of at least one of the length and width dimension of the filter element divided by the respective length or width dimension of the sensor element is a non-integer greater than 1.

### BRIEF DESCRIPTION OF THE DRAWINGS

FIG. 1 illustrates a simplified example of a 6×6 portion of a sensor array.

FIG. 2 illustrates a simplified example of a 4×4 portion of a color filter array.

FIG. 3 illustrates the example of FIG. 2 with an alternative color filter array configuration.

FIG. 4 illustrates the example of FIGS. 2 and 3 with an alternative color filter configuration.

FIG. 5 illustrates a 6×6 portion of a sensor array with a 4×4 portion of a color filter applied to it, where the length and width of color filter elements are 1.5× of the sensors.

FIG. 6 illustrates the example of FIG. 3, emphasizing the color filter elements against the sensor area, where the length and width of color filter elements are 1.5× of the sensors.

FIG. 7 illustrates an example of a size reduced pattern of a color filter array and sensor array where the length and width of color filter elements are 1.5× of the sensors.

FIG. 8 illustrates an example of a 1.5:1 color filter element to sensor element configuration.

FIG. 9 illustrates an example of a color filter arrangement having a 3×3 pattern that may be repeated throughout the filter.

FIG. 10 illustrates an example of a configuration where the color filter elements are 2.5× the size of the sensors.

FIG. 11 illustrates an example of a configuration where the color filter elements are 1.1× the size of the sensors.

FIG. 12 illustrates an example of a size reduced pattern of a color filter array and sensor array where the length and width of color filter elements are 1.5× of the sensors, and the sensors of the sensor array have an aspect ratio of 2:1.

FIG. 13 illustrates an example of a 1.5:1 color filter element to sensor element configuration where the sensors have an aspect ratio of 2:1.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

The term “non-integer ratio” is used herein to define a ratio where at least one of the numbers of the ratio will be expressed with a fractional component when the ratio is simplified such that the first number of the ratio or the second number of the ratio is “1.” For example, a ratio of 1:1.5 contains the number 1 being a whole number, and the number 1.5 being expressed with a fractional component; the fractional component being the “0.5” or one-half. In the context of the ratios described herein, any two things measured with respect to each other may not be the exact size described, but the numbers herein are meant to be described such that the two things are substantially equal to the measurement expressed.

The term “about” and “substantially” as used herein indicates a tolerance within 10% of the measurement expressed, unless otherwise stated.

The term “light” as used herein refers to wavelengths of radiation that are visible and non-visible to a human eye.

The words “color filter array,” “filter array,” and “filter element” are broad terms and are used herein to mean any form of filtering technology associated with filtering spectrums of electromagnetic radiation, including visible and non-visible wavelengths of light.

The term “image sensor” as used herein may also be referred to as a “sensor.”

The term “color filter array” or CFA may be referred to as a “filter array,” “color filters,” “RGB filters,” or “electromagnetic radiation filter array.” When a filter is referred to as a red filter, a blue filter, or a green filter, such filters are configured to allow light to pass through that has one or more wavelengths associated with the color red, blue, or green, respectively.

The term “respective” is used herein to mean the corresponding apparatus associated with the subject. When a filter is referenced to a certain color (e.g., a red filter, a blue filter, a green filter) such terminology refers to a filter configured to allow the spectrum of that color of light to pass through (e.g., wavelengths of light that are generally associated with that color).

The following detailed description is directed to certain specific embodiments of the invention. However, the invention can be embodied in a multitude of different ways. It should be apparent that the aspects herein may be embodied in a wide variety of forms and that any specific structure, function, or both being disclosed herein is merely representative. Based on the teachings herein one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to, or other than one or more of the aspects set forth herein.

The examples, systems, and methods described herein are described with respect to digital camera technologies. The systems and methods described herein may be implemented on a variety of different photosensitive devices, or image sensors. These include general purpose or special purpose image sensors, environments, or configurations. Examples of photosensitive devices, environments, and configurations that may be suitable for use with the invention include, but are not limited to, semiconductor charge-coupled devices (CCD) or active sensors in CMOS or N-Type metal-oxide-semiconductor (NMOS) technologies, all of which can be germane in a variety of applications including: digital cameras, hand-held or laptop devices, and mobile devices (e.g., phones, smart phones, Personal Data Assistants (PDAs), Ultra Mobile Personal Computers (UMPCs), and Mobile Internet Devices (MIDs)).

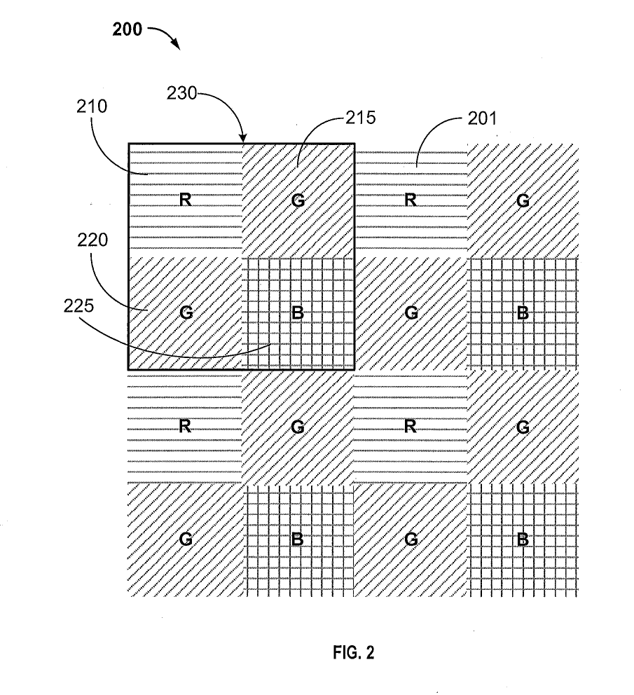

Embodiments disclosed herein may include a solution for overcoming the manufacturing difficulties associated with producing a sub-micron sensor (e.g., a sensor below 1.1 μm in size) with a Color Filter Array (CFA) (for example, FIG. 2) that can provide accurate filter function for individual sensors. Current state-of-the-art CFA technology can only support sensor sizes down to about 1.1 μm in resolution using the standard 1:1 color filter-to-sensor ratio. To accommodate smaller sensor sizes while maintaining acceptable color error and achieving high color fidelity and uniformity, individual color filter elements may extend across multiple sensors, and individual sensors may share portions of multiple color filter elements that mask separate segments of an individual sensors.

In some examples, a fractional color filter-to-sensor ratio is used where the size of each individual color filter element of the CFA is greater than the size of the sensors in the sensor array. The result is an overlap of the multiple colors on individual sensors. For example, in an embodiment where the color filters are 1.5× the size of the individual sensors (e.g., a 1.5:1 ratio), and the colors used in the color filters are Red, Green, and Blue (RGB), the combination of colors as seen by the sensors through the color filters can expand the spectrum of colors beyond RGB to also include Cyan, Yellow, and White, representing the expanded spectrum of light seen by individual sensors.

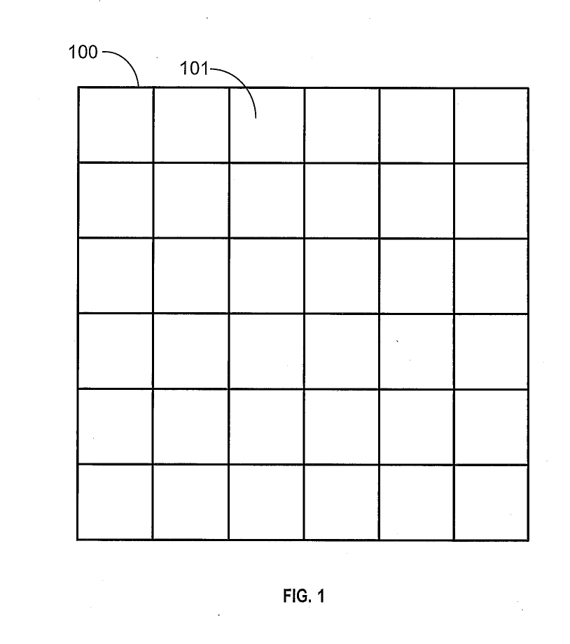

FIG. 1 illustrates an example array of sensors (or sensors) 100, where each individual sensor 101 is represented as a square having a 1:1 sensor aspect ratio, having the width of the individual sensor 101 substantially equal to the length of that individual sensor 101. This example should not be read as limiting, as the present invention may be applied to an array of sensors 100 using an alternative sensor element aspect ratio (e.g., sensor aspect ratio 2:1, 4:3, and 5:4). FIG. 1 provides an example 6×6 square array of sensors 100, including 36 individual sensors in total. This example should not be read as limiting, as various implementations may be applied to a sensor array containing any number of sensors.

In one example embodiment, the array of sensors 100 may comprise a semiconductor CCD, or any device consisting of a photoactive region (or an epitaxial layer of silicon) integrated with a transmission region coupled to a shift register. In an example embodiment of a CCD for capturing images, an image may be projected through a lens onto the array of sensors 100 that includes a capacitor array, causing each capacitor to accumulate an electric charge proportional to the light intensity at that location.

Alternatively, the array of sensors 100 may comprise an active sensor (also referred to herein as a CMOS sensor), or any device consisting of an integrated circuit containing an array of sensors 100, each sensor containing a photodetector and an active amplifier. In this embodiment, the array of sensors 100 may be arranged in rows and columns. In some examples, individual sensors in a given row may share reset lines, so that a whole row may be reset at one time. The row select lines of each sensor in a row may also be connected. The output of each sensor in any given column are may be connected to together forming a single output terminal (or line). Only one row is selected at a given time, so no “competition” for the output line occurs. Amplifier circuitry to amplify sensor output may be provided on a column basis.

In another example embodiment, the array of sensors 100 may comprise an NMOS, or any image sensor consisting of n-type transistors to construct the on-chip logic of an image sensor.

FIG. 2 illustrates an example color filter array (CFA) 200 that includes an array of individual filters. In FIGS. 2, 3 and 8, an illustrated pattern of horizontal lines, diagonal lines, and cross-hatching of vertical lines and horizontal lines is merely a depicted representation of a filter and such lines do not represent any physical structure of a filter. In this example, the CFA 200 is made up of a 4×4 CFA 200 illustrated as patterned squares, each square representing an individual filter 201 designed to pass a particular range of wavelengths, and each square labeled with an alphabetical letter representative of the color of light that may pass through that particular filter: the letter R referring to red, the letter G referring to green, and the letter B referring to blue. The CFA 200 may comprise a 2×2 filter array that represents a repeatable pattern of recurring filter elements 230 as illustrated by the bold border square in the upper left-hand corner of the CFA 200 of FIG. 2. For example, the pattern of recurring filter elements 230 can include a first filter element 210, located in the top left hand corner of the pattern of recurring filter elements 230, which is represented in FIG. 2 by a horizontal line pattern and the letter “R” in the center indicating the first filter element 210 is a red filter configured to pass light having one or more wavelengths associated with the color red. The pattern of recurring filter elements 230 may also include a second filter element 215 disposed adjacent and to the right of the first filter element 210 and a third filter element 220 disposed adjacent and below the first filter element 210. The second filter element 215 and third filter element 220 are both illustrated as having a diagonal line pattern with the letter “G” in the center, indicating both the second filter element 215 and third filter element 220 are green filters configured to pass light having one or more wavelengths associated with the color green. The pattern of recurring filter elements 230 may also include a fourth filter element 225 located directly adjacent to both the second filter element 215 and third filter element 220 and diagonally adjacent to the first filter element 210. The fourth filter element 225 is illustrated as a square with a cross-hatch pattern of vertical and horizontal lines, and containing the letter “B” indicating a blue filter configured to pass light having one or more wavelengths generally associated with the color blue. This 2×2 arrangement, an example of a pattern of recurring filter elements 230 (illustration emphasized by a square with thick boundary lines) is repeated to create the 4×4 CFA 200 illustrated by FIG. 2.

The CFA 200 may mask an array of sensors 100 in order to filter radiation and allow only a specific range of wavelengths, such that each individual filter 201 included in the CFA 200 allows the corresponding sensors to be exposed to only a specific range of the electromagnetic spectrum, based on the configuration of the individual filters, for example, first filter element 210, second filter element 215, third filter element 220, and fourth filter element 225 of the CFA 200. FIG. 2 is an example that illustrates the Bayer filter configuration discussed above, where the RGB color filters limit the light exposed to the sensors to RGB wavelength regions. This example should not be read as limiting, as the present invention may comprise alternative configurations of color patterns and size of color filters, as well as filters that allow for passing ranges of electromagnetic frequencies that include infrared, ultra-violet, or other ranges of the electromagnetic spectrum beyond visible light.

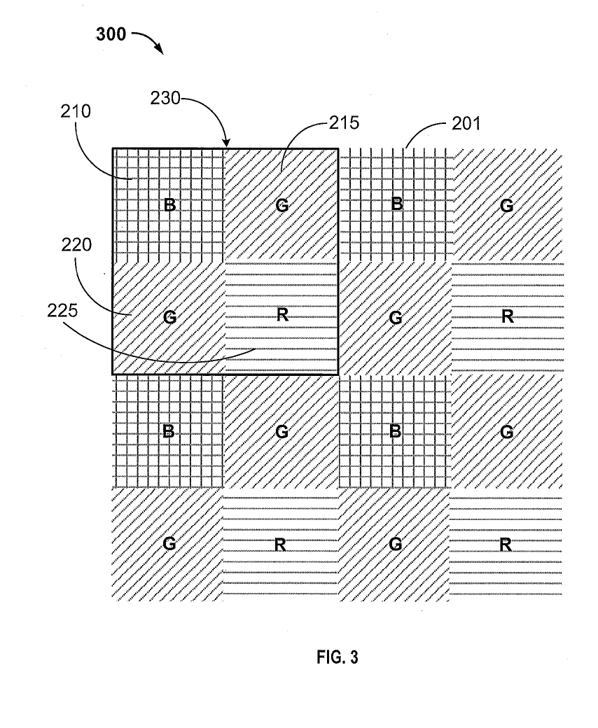

For example, FIG. 3 illustrates an alternative CFA configuration that includes a 2×2 filter array representative of a repeatable pattern of recurring filter elements 230 as illustrated by the bold border square in the upper left-hand corner of the CFA 300. The pattern of recurring filter elements 230 can include a first filter element 210, located in the top left hand corner of the pattern of recurring filter elements 230, which is represented in FIG. 3 by a square with a cross-hatch pattern of vertical and horizontal lines, and containing the letter B indicating a blue filter. The pattern of recurring filter elements 230 may also include a second filter element 215 disposed adjacent and to the right of the first filter element 210 and a third filter element 220 disposed adjacent and below the first filter element 210. The second filter element 215 and third filter element 220 are both illustrated as having a diagonal line pattern with the letter G in the center, indicating both the second filter element 215 and third filter element 220 are green filters. The pattern of recurring filter elements 230 may also include a fourth filter element 225 located directly adjacent to both the second filter element 215 and third filter element 220 and diagonally adjacent to the first filter element 210. The fourth filter element 225 is illustrated as a horizontal line pattern and the letter R in the center indicating the fourth element 225 is a red filter. This 2×2 arrangement, an example of a pattern of recurring filter elements 230 (illustration emphasized by a square with thick boundary lines) is repeated to create the 4×4 CFA 300 illustrated by FIG. 3.

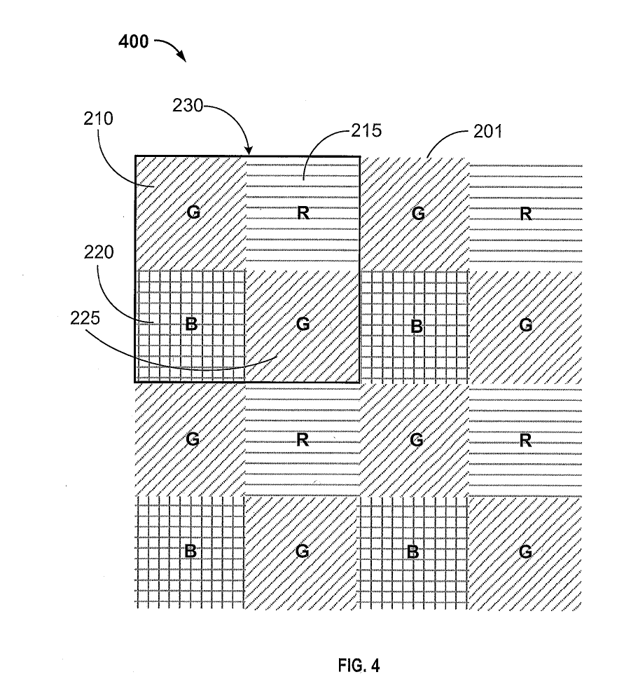

Another example of an alternative configuration is provided in FIG. 4. FIG. 4 illustrates an alternative CFA configuration that includes a 2×2 filter array that represents a repeatable pattern of recurring filter elements 230 as illustrated by the bold border square in the upper left-hand corner of the CFA 400. For example, the pattern of recurring filter elements 230 can include a first filter element 210, located in the top left hand corner of the pattern of recurring filter elements 230, which is represented in FIG. 4 as a square having a diagonal line pattern with the letter G in the center, indicating that the first filter element 210 is a green filter designed to pass an associated wavelength. The pattern of recurring filter elements 230 may also include a second filter element 215 disposed adjacent and to the right of the first filter element 210 and a third filter element 220 disposed adjacent and below the first filter element 210. The second filter element 215 is illustrated as a horizontal line pattern and the letter R in the center to indicate the general range of passable wavelengths. The third filter element 220 is illustrated as having cross-hatch pattern of vertical and horizontal lines, and containing the letter B indicating a blue filter designed to pass an associated wavelength. The pattern of recurring filter elements 230 may also include a fourth filter element 225 located directly adjacent to both the second filter element 215 and third filter element 220 and diagonally adjacent to the first filter element 210. The fourth filter element 225 is illustrated as a diagonal line pattern with the letter G in the center, indicating that the fourth filter element 225 is a green filter designed to pass an associated wavelength. This 2×2 arrangement, an example of a pattern of recurring filter elements 230 (illustration emphasized by a square with thick boundary lines) is repeated to create the 4×4 CFA 400 illustrated by FIG. 4.

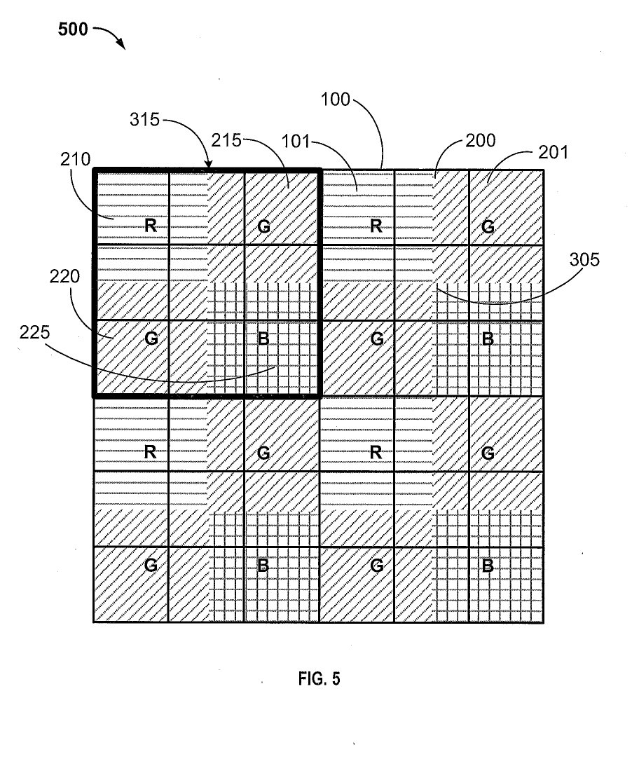

As previously discussed, the size of each individual filter 201 of a typical CFA 200, when compared to the size of an individual sensor 101 in the array of sensors 100, operate using a 1:1 ratio, where an individual filter 201 designed to filter a specific range of wavelengths corresponds to a single sensor and is disposed contiguous to that single sensor. For example, an individual filter of a typical CFA corresponds to an individual sensor such that the light being filtered by the filter propagates to only that sensor. FIG. 5 illustrates an example embodiment, where the size ratio of each individual filter 201 of the CFA 200 to each individual sensor 101 of the array of sensors 100 is 1.5:1. In this example, each individual filter 201 is 1.5 times the length and the width of the individual sensor 101 it is disposed over, causing each individual filter 201 to be disposed over multiple sensors. FIG. 5 further illustrates the 6×6 array of sensors 100 of FIG. 1 merged into the CFA 200 of FIG. 2 to provide an example configuration of the CFA 200 and array of sensors 100 embodied in the present invention. In this configuration, the individual filters of the CFA 200 are 1.5× the size of the individual sensors of the array of sensors 100, and each individual sensor 101 is of a standard 1:1 length and width ratio having the width of the individual sensor 101 substantially equal to the length of that individual sensor 101. This configuration may create instances of up to four separate adjacent filters disposed over a center sensor 305 once in every 3×3 array of nine sensors 310 as explained in more detail below. This example should not be read as limiting.

As previously mentioned, FIG. 5 illustrates how the example configuration can result in an individual sensor 101 being masked by more than one individual filter 201. In this example, center sensor 305 may be masked by two green filters, a red filter, and a blue filter, the filters each covering one-quarter of the light sensing surface of the sensor. The two sensors directly 510, 520 above and directly to the left of center sensor 305 are each masked by two filters, where half of the light sensing surface of the sensors are masked by a red filter, and the other half by a green filter. The two sensors 525, 515 directly below and directly to the right of the center sensor 305 are each masked by two filters, where half of the light sensing surface of the sensors are masked by a blue filter, and the other half by a green filter. This creates the added benefit of expanding the spectral range filtered to certain sensors to include not just red, green, and blue wavelengths, but also cyan, yellow, and white (RGBCYW).

The CFA 200 in FIG. 5 is a mosaic of individual color filters. The CFA 200 is made up of a 4×4 CFA 200 illustrated as patterned squares, each square representing an individual filter 201 and labeled with an alphabetical letter representative of the color of light that may pass through that particular filter. The letter R referring to red, the letter G referring to green, and the letter B referring to blue. The CFA 200 includes a first filter element 210, located in the top left hand corner of the matrix, which is made up of a horizontal line pattern and the letter R in the center to indicate the general range of passable wavelengths. The CFA 200 also includes a second filter element 215 disposed adjacent to the first filter element 210 and to the right of the first filter element 210 (relative to FIG. 5 orientation) and a third filter element 220 disposed adjacent to the first filter element 210 and below first filter element 210 (relative to FIG. 5 orientation). Second filter element 215 and third filter element 220 are both illustrated as having a diagonal line pattern with the letter G in the center, indicating both the second filter element 215 and the third filter element 220 are green filters designed to pass an associated wavelength. The CFA also includes a fourth filter element 225 located directly adjacent to both the green filters 215, 220 and diagonally adjacent to the red filter 210, is made up of a cross-hatch pattern of vertical and horizontal lines, and contains the letter B indicating a blue filter.

FIG. 5 further illustrates an example configuration 500 of a recurring element 315 in the array of sensors 100 and filter CFA 200 configuration. The recurring element 315 is emphasized by a dark outlined square in the upper left corner of FIG. 5, the dark outlined square containing nine individual sensors in a square, 3×3 formation and four color filter elements in a square 2×2 formation disposed over the individual sensors. The four color filter elements representing red 210, green 215, blue 225, and green 220, respectively (clockwise from upper left corner).

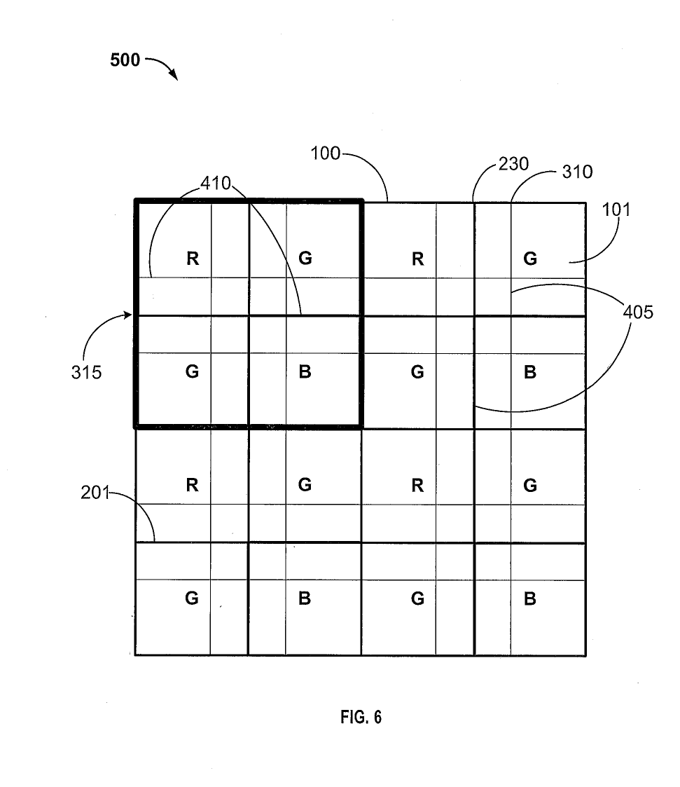

FIG. 6 provides an exemplary view of a pattern of recurring filter elements 230 and array of sensors 100 where the individual filters 201 are demarcated in the Figure by thick boundary lines and the array of sensors 100 is demarcated by thinner lines to provide an additional perspective of one embodiment of the present invention where the CFA 200 to array of sensors 100 ratio is 1.5:1. FIG. 6 is provided to show clarity of an example embodiment of the invention, and comprises a combination of FIG. 1 and FIG. 2, but removes the patterns contained in FIG. 2, and instead uses vertical 405 and horizontal 410 boundary lines to illustrate an example embodiment of the invention. Light-weighted boundary lines denote the boundaries of each individual sensor 101, while the heavier weighted lines denote the boundaries of each individual filter 201. Note that the lines are depicted only for visualization purposes.

FIG. 6 further illustrates an example of a recurring element 315 in the array of sensors 100 and filter CFA 200 configuration. The recurring element 315 is emphasized by a dark outlined square in the upper left corner of FIG. 6, the dark outlined square containing nine individual sensors in a square, 3×3 formation, and four color filter elements in a square, 2×2 formation adjacent to the individual sensors. The four color filter elements representing red, green, blue, and green, respectively (clockwise from upper left corner).

FIGS. 5 and 6 both provide an additional exemplary view of the recurring pattern of a CFA 200 and the array of sensors 100 using the 1.5:1 ratio defined in FIGS. 3 and 4.

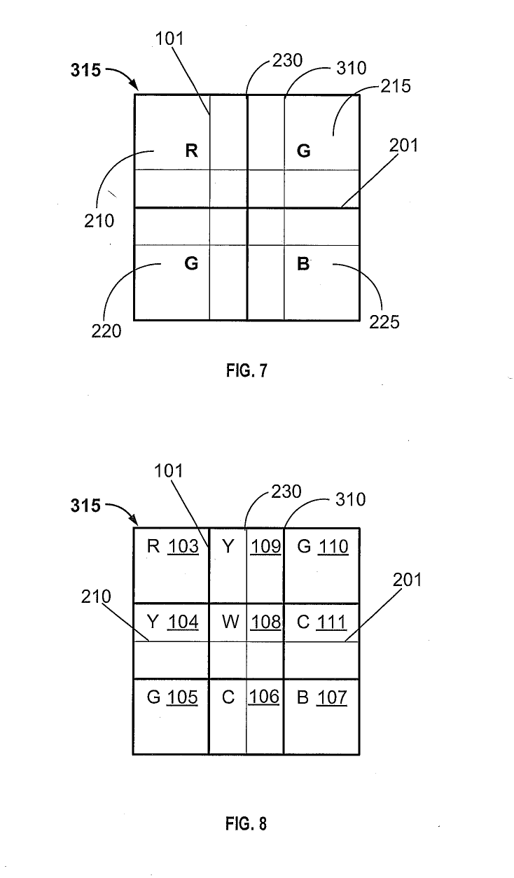

FIG. 7 comprises a 2×2 arrangement, an example pattern of recurring filter elements 230 (emphasized using thick borders around each filter element for visualization purposes) enclosing four squares, each square representing in individual filter 201 in an array of four color filters, the top left filter (e.g., first filter element 210) containing a letter R for red, the two immediately adjacent to the second filter element 215 and the third filter element 220 containing the letter G referring to green, and the fourth filter element 225 letter B referring to blue. The color labels of these filters generally representing the wavelength allowed to pass through each filter. The 2×2 color filter array of FIG. 7 is disposed adjacent to the 3×3 array of nine sensors 310 such that the ratio of color filters to sensors is 1.5:1, resulting in the 2×2 arrangement of color filters substantially matching the 3×3 array of nine sensors 310.

FIG. 8 illustrates the concept discussed briefly above where the use of multiple color filters on one sensor expands the spectrum of colors from RGB to RGBCYW. In this example embodiment, the 2×2 color filter array may be disposed over the 3×3 array of nine sensors 310 (emphasized using thick borders around each sensor element for visualization purposes) such that the ratio of color filters to sensors is 1.5:1. This results in the 2×2 arrangement of color filters substantially matching the 3×3 array of nine sensors 310. Here, the first sensor 103 can be masked completely by a first filter element 210, where the first filter element 210 may be configured to pass a spectrum of red light. Thus, the first sensor 103 may be exposed to a spectrum of light that is limited by the first filter element 210. A second sensor 104, situated substantially below (in the orientation of FIG. 8) the first sensor 103, may be masked by two CFA filters (in this example, the first filter element 210 and a second filter element 215). Each CFA filter element may be positioned to mask portions of the second sensor 104. In this example, the second sensor 104 may be exposed to a combination of green and red wavelengths resulting in a light spectrum that can be broad enough to include orange (590-620 nm wavelength), yellow (570-590 nm wavelength), and lighter shades of green (490-550 nm wavelength) to the second sensor 104. A third sensor 109, which lies adjacent and directly to the right of the first sensor 103, may experience the same broad spectrum of light caused by a similar combination of filter elements. The third sensor 109 may be masked by the first filter element 210 and the second filter element 215. Due to both the second sensor 104 and third sensor 109 experiencing a broader spectrum of radiation that may include the color yellow, both sensors are labeled with a “Y.”

FIG. 8 further illustrates a fourth sensor 105 on the bottom row of the 3×3 array of nine sensors 310 adjacent to, and directly below the second sensor 104. The 2×2 filter matrix can be arranged so that the fourth sensor 105 is masked completely by the third filter element 220, where the third filter element 220 may be configured to pass a spectrum of green light. Thus, a light sensing element of the fourth sensor 105 may be exposed to a spectrum of light that is limited by the third filter element 220. A fifth sensor 110, which lies adjacent and directly to the right of the third sensor 109, may experience the same filtered light spectrum as the fourth sensor 105. Due to both the fourth sensor 105 and fifth sensor 110 experiencing a spectrum of radiation that may be limited to the color green, both sensors are labeled with a “G.”

Additionally, FIG. 8 further illustrates a sixth sensor 106 on the bottom row of the 3×3 array of nine sensors 310 adjacent and directly to the right (in the orientation of FIG. 8) of the fourth sensor 105. The sixth sensor 106 can be masked by two individual CFA filters (in this example, the third filter element 220 and the fourth filter element 225). Each CFA filter element may be positioned to mask portions of the sixth sensor 106. In this example, the sixth sensor 106 may be exposed to a combination of green and blue wavelengths resulting in a light spectrum that can include the color cyan (490-520 nm wavelength). A seventh sensor 111, which lies adjacent and directly below (in the orientation of FIG. 8) the fifth sensor 110, may experience the same spectrum of light caused by the combination of filter elements masking the sixth sensor 106. The seventh sensor 111 can be masked by the second filter element 215 and the fourth filter element 225. Due to both the sixth sensor 106 and seventh sensor 111 experiencing a broad spectrum of radiation that may include the color cyan, both sensors are labeled with a “C.”

FIG. 8 further illustrates an eighth sensor 107 on the bottom row of the 3×3 array of nine sensors 310 adjacent to, and directly below (in the orientation of FIG. 8) the seventh sensor 111. The 2×2 filter matrix can be arranged so that the eighth sensor 107 is masked completely by the fourth filter element 225, where the fourth filter element 225 may be configured to pass a spectrum of blue light. Thus, a light sensing element of the eighth sensor 107 may be exposed to a spectrum of light that is limited by the fourth filter element 225. Due to the eighth sensor 107 experiencing a spectrum of radiation that may be limited to the color blue, it is labeled with a “B.”

FIG. 8 illustrates a ninth sensor 108 in the center of the 3×3 array of nine sensors 310. The 2×2 filter matrix can be arranged so that the ninth sensor 108 is masked 25% by the first filter element 210, 25% by the second filter element 215, 25% by the third filter element 220, and 25% by the fourth filter element 225. Thus, a light sensing element of the ninth sensor 108 may be exposed to a spectrum of light that is broader than the spectrum exposed to the remaining sensors in the 3×3 array of nine sensors 310. Due to the broad spectrum of light that the ninth sensor 108 may be exposed to, it is labeled with a “W” indicating that the pixel may be exposed to a mixture of the frequencies allowed by the filter elements. The resulting array has an effective sensor composition of 11% R, W, and B, respectively and 22% G and C, respectively.

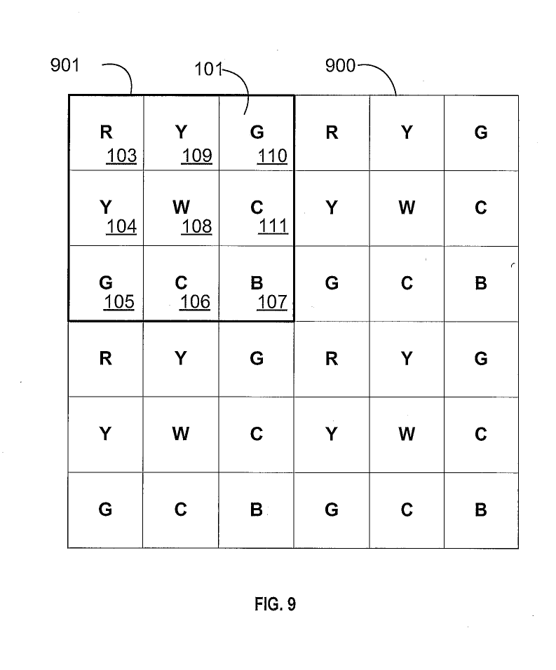

FIG. 9 illustrates the example embodiment of FIG. 8 applied to the array of sensors 100 of FIG. 1. FIG. 9 also includes one letter labels on each individual sensor 101 identifying the spectrum of light exposed to the individual sensor 101 using the example embodiment described in FIG. 8.

FIG. 9 shows a 6×6 array of small squares representative of a sensor array 900, or a portion of a sensor array 900, with each square containing an alphabetical letter. The array 900 can be viewed as being a repeated pattern of four, 3×3 sensor arrays. Each 3×3 sensor array 901 containing a first sensor 103 (represented by a first square) in the top left corner representing a sensor and containing the letter R signifying the light received by that sensor is red. The two sensors 104, 109 immediately adjacent to the top left sensor 103 and containing the letter “Y” indicating light received by those sensors is yellow. Directly adjacent to both yellow sensors 104, 109, and diagonally adjacent to the red sensor 103 is a sensor labeled with a “W” (ninth sensor 108), indicating that the ninth sensor 108 receives white light due to the combination of RGB filters (e.g., the four filter elements previously discussed) overlapping the ninth sensor 108. Diagonally adjacent to the ninth sensor 108 and directly adjacent to the yellow sensors 104, 109 are two sensors 105, 110 with the letter “G” signifying that this sensor receives a green light due to the green color filter. Directly adjacent to the ninth sensor 108 and on opposite ends of the ninth sensor 108 in relation to the yellow sensors, are two sensors 106, 111 labeled with the letter “C.” The color these sensors are exposed to is cyan due to the overlap of green and blue filters over these sensors (sixth sensor 106 and seventh sensor 111). Finally, directly adjacent to the cyan sensors (sixth sensor 106 and seventh sensor 111) and diagonally adjacent to a ninth sensor 108 is a sensor labeled with a B (eighth sensor 107), which represents a sensor that receives light that propagates through a blue filter.

As explained below, the size of the individual filter 201 may vary with respect to the individual sensor 101, resulting in varying spectrums of light exposed to the individual sensor 101 masked by a plurality of individual color filters. To illustrate this, in a 1.1:1 CFA 200 to array of sensors 100 ratio (discussed below) where the filter element is only 1.1 times larger than a corresponding sensor element, second sensor 104 would have a much smaller spectrum of red light with respect to the spectrum of green light it receives.

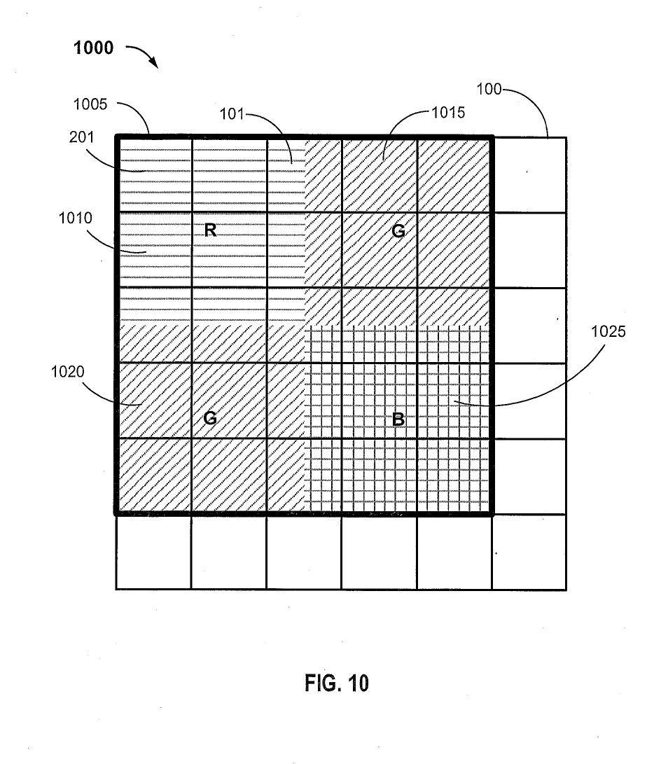

FIG. 10 illustrates an example configuration where the individual color filters are 2.5× the size of the individual sensor 101. Similar to FIG. 5, FIG. 10 provides a 6×6 array of sensors 100 merged with an electromagnetic radiation filter array 1005. It should be noted that the size of the individual filter 201 may vary with respect to the size and shape of the individual sensor 101.

FIG. 10 illustrates an example embodiment 1000, where the size ratio of individual filter 201 of the electromagnetic radiation filter array 1005 to each individual sensor 101 of the array of sensor elements 100 is 2.5:1. In this example, the length of an individual filter 201 is 2.5 times the length and the width of an individual sensor 101. In this configuration, each individual sensor 101 is of a standard 1:1 length and width ratio having the width of the individual sensor 101 substantially equal to the length of that individual sensor 101. This configuration may create instances of up to four separate filters disposed adjacent to center sensor 305 once in every group of thirty-six sensors as explained in more detail below. This example should not be read as limiting, as the present invention may be applied to an array of sensor elements 100 using an alternative sensor aspect ratio (e.g., sensor aspect ratio 2:1, 4:3, 5:4, etc.), or electromagnetic radiation filter array 1005 using an alternative aspect ratio.

The electromagnetic radiation filter array 1005 in FIG. 10 includes a mosaic of individual color filters. The electromagnetic radiation filter array 1005 is made up of a 2×2 filter array illustrated as patterned squares, each square representing an individual filter 201 and labeled with an alphabetical letter representative of the color of light that may pass through that particular filter. In this example, the letter R referring to red, the letter G referring to green, and the letter B referring to blue. The electromagnetic radiation filter array 1005 includes a first filter 1010, located in the top left hand corner of the matrix, which is made up of a horizontal line pattern and the letter R in the center to indicate an example range of passable wavelengths. The electromagnetic radiation filter array 1005 also includes a second filter 1015 disposed adjacent and directly to the right (in the orientation of FIG. 10) of the first filter element 210, and a third filter 1020 disposed adjacent and directly below the first filter 1010. Second filter 1015 and third filter 1020 are both illustrated as having a diagonal line pattern with the letter G in the center, indicating both the second filter 1015 and third filter 1020 are designed to pass an associated wavelength. The CFA 200 also includes a fourth filter 1025 located directly adjacent to both the second filter 1015 and third filter 1020 and diagonally adjacent to the first filter 1010, is made up of a cross-hatch pattern of vertical and horizontal lines, and contains the letter B to indicate an example range of passable wavelengths.

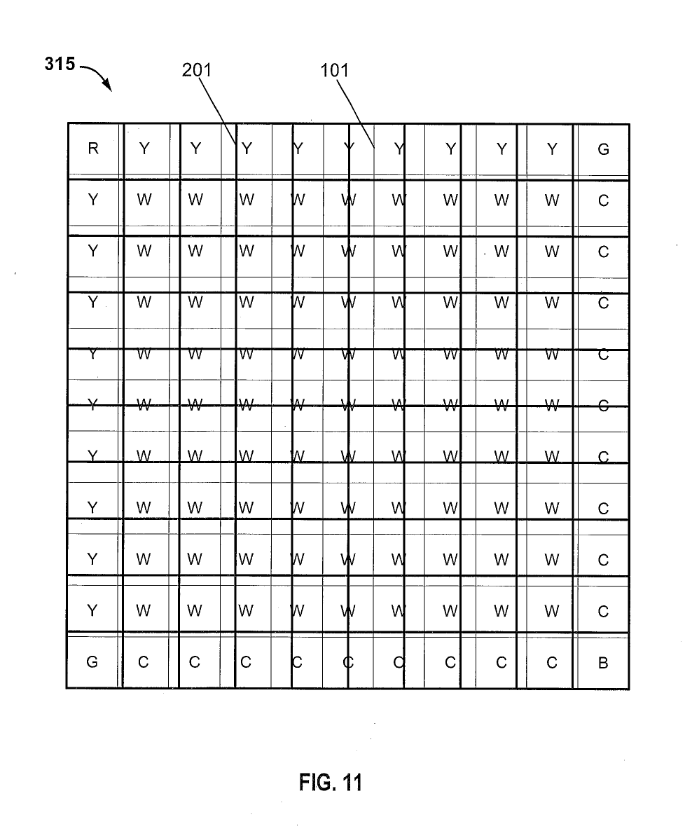

FIG. 11 illustrates an example embodiment where the size ratio of individual filter 201 to a corresponding sensor 101 is 1.1:1. In this example, the length of an individual filter 201 is 1.1 times the length and the width of an individual sensor 101. In this configuration, each individual sensor 101 is of a standard 1:1 length and width ratio having the width of the individual sensor 101 substantially equal to the length of that individual sensor 101.

The recurring element 315 in the array of sensor elements and filter CFA configuration of FIG. 11 includes a 10×10 matrix of filter elements, and an 11×11 matrix of sensor elements. The filter elements are emphasized with a bolder outline than the boundary of the sensor elements for visualization purposes. Each sensor element is labeled with a letter indicating the range of electromagnetic radiation it is exposed to. For example, sensor elements containing the letter R refers to red, G refers to green, B refers to blue, C refers to cyan, Y refers to yellow, and W refers to white. It is noted that in this example configuration that there is a large number of sensor elements exposed to all three spectrums of R, G, and B. This kind of configuration may be a useful CFA for photodiodes that respond to all colors of light; that is, where some or all of the sensor elements are “panchromatic”, and more of the light is detected, rather than absorbed, compared to the traditional Bayer matrix.

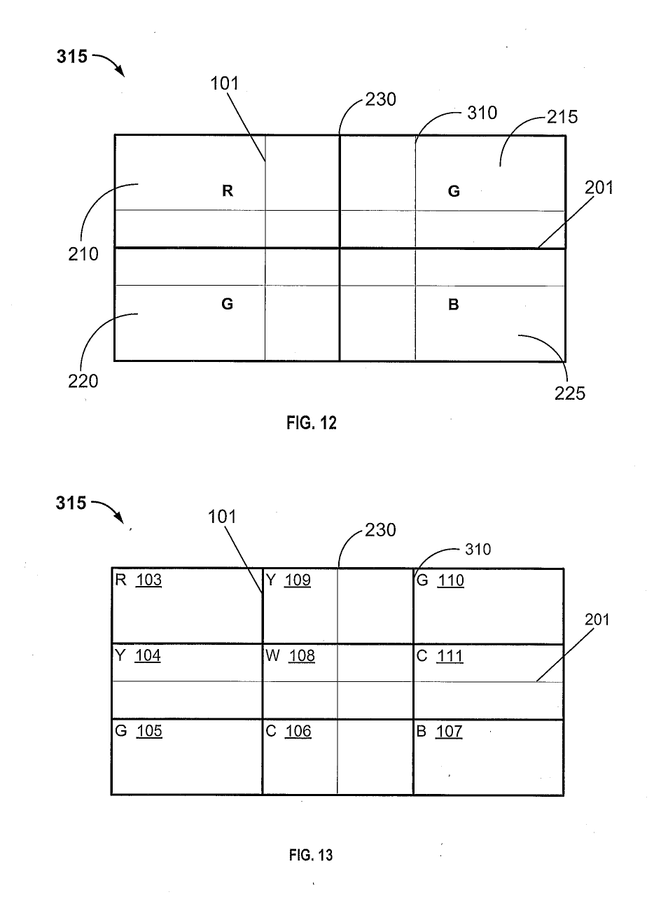

FIG. 12 comprises an example 2×2 arrangement, an example pattern of color filter elements 230 that are 1.5× the size of the associated pixels, the pixels having an aspect ratio of 2:1. This example pattern of recurring filter elements 230 is represented by four squares (emphasized using thick borders around each filter element), each square representing an individual filter 201 in an array of four color filters, the top left filter (e.g., first filter element 210) containing a letter R for red, the two immediately adjacent to the second filter element 215 and the third filter element 220 containing the letter G referring to green, and the fourth filter element 225 letter B referring to blue. The color labels of these filters generally representing the wavelength allowed to pass through each filter. The 2×2 color filter array of FIG. 12 is disposed adjacent to the 3×3 array of nine sensors 310 such that the ratio of color filters to sensors is 1.5:1, resulting in the 2×2 arrangement of color filters substantially matching the 3×3 array of nine sensors 310.

FIG. 13 illustrates the concept discussed briefly above and in FIG. 12 regarding the use of multiple color filters a sensor with a 2:1 aspect ratio. In this example embodiment, the 2×2 color filter array may overlay the 3×3 array of nine sensors 310 such that the ratio of color filters to sensors is 1.5:1. This results in the 2×2 arrangement of color filters substantially matching the 3×3 array of nine sensors 310. Here, the first sensor 103 can be masked completely by a first filter element 210, where the first filter element 210 may be configured to pass a spectrum of red light. Thus, a light sensing element of the first sensor 103 may be exposed to a spectrum of light that is limited by the first filter element 210. A second sensor 104, situated substantially below the first sensor 103, may be masked by two CFA filter elements (in this example, the first filter element 210 and a second filter element 215). Each CFA filter element may be positioned to mask portions of the second sensor 104. In this example, the second sensor 104 may be exposed to a combination of green and red wavelengths resulting in a light spectrum that can be broad enough to include orange (590-620 nm wavelength), yellow (570-590 nm wavelength), and lighter shades of green (490-550 nm wavelength) to the second sensor 104. A third sensor 109, which lies adjacent and directly to the right of the first sensor 103, may experience the same broad spectrum of light caused by a similar combination of filter elements. The third sensor 109 may be masked by the first filter element 210 and the second filter element 215. Due to both the second sensor 104 and third sensor 109 experiencing a broader spectrum of radiation that may include the color yellow, both sensors are labeled with a “Y.”

FIG. 13 further illustrates a fourth sensor 105 on the bottom row of the 3×3 array of nine sensors 310 adjacent to, and directly below the second sensor 104. The 2×2 filter matrix can be arranged so that the fourth sensor 105 is masked completely by the third filter element 220, where the third filter element 220 may be configured to pass a spectrum of green light. Thus, a light sensing element of the fourth sensor 105 may be exposed to a spectrum of light that is limited by the third filter element 220. A fifth sensor 110, which lies adjacent and directly to the right of the third sensor 109, may experience the same filtered light spectrum as the fourth sensor 105. Due to both the fourth sensor 105 and fifth sensor 110 experiencing a spectrum of radiation that may be limited to the color green, both sensors are labeled with a “G.”

Additionally, FIG. 13 further illustrates a sixth sensor 106 on the bottom row of the 3×3 array of nine sensors 310 adjacent and directly to the right (in the orientation of FIG. 8) of the fourth sensor 105. The sixth sensor 106 can be masked by two individual CFA filters (in this example, the third filter element 220 and the fourth filter element 225). Each CFA filter element may be positioned to mask portions of the sixth sensor 106. In this example, the sixth sensor 106 may be exposed to a combination of green and blue wavelengths resulting in a light spectrum that can be broad enough to include the color cyan. A seventh sensor 111, which lies adjacent and directly below (in the orientation of FIG. 8) the fifth sensor 110, may experience the same broad spectrum of light caused by a similar combination of filter elements. The seventh sensor 111 can be masked by the second filter element 215 and the fourth filter element 225. Due to both the sixth sensor 106 and seventh sensor 111 experiencing a broad spectrum of radiation that may include the color cyan, both sensors are labeled with a “C.”

FIG. 13 further illustrates an eighth sensor 107 on the bottom row of the 3×3 array of nine sensors 310 adjacent to, and directly below (in the orientation of FIG. 8) the seventh sensor 111. The 2×2 filter matrix can be arranged so that the eighth sensor 107 is masked completely by the fourth filter element 225, where the fourth filter element 225 may be configured to pass a spectrum of blue light. Thus, a light sensing element of the eighth sensor 107 may be exposed to a spectrum of light that is limited by the fourth filter element 225. Due to the eighth sensor 107 experiencing a spectrum of radiation that may be limited to the color blue, it is labeled with a “B.”

FIG. 13 illustrates a ninth sensor 108 in the center of the 3×3 array of nine sensors 310. The 2×2 filter matrix can be arranged so that the ninth sensor 108 is masked 25% by the first filter element 210, 25% by the second filter element 215, 25% by the third filter element 220, and 25% by the fourth filter element 225. Thus, a light sensing element of the ninth sensor 108 may be exposed to a spectrum of light that is broader than the spectrum exposed to the remaining sensors in the 3×3 array of nine sensors 310. Due to the broad spectrum of light that the ninth sensor 108 may be exposed to, it is labeled with a “W” indicating that the pixel may be exposed to a mixture of the frequencies allowed by the filter elements.

### Implementing Systems and Terminology

Implementations disclosed herein provide systems, methods and apparatus for using values received from imaging diodes to calculate values for use in a phase detection autofocus process. One skilled in the art will recognize that these embodiments may be implemented in hardware, software, firmware, or any combination thereof.

In some embodiments, the circuits, processes, and systems discussed above may be utilized in a wireless communication device. The wireless communication device may be a kind of electronic device used to wirelessly communicate with other electronic devices. Examples of wireless communication devices include cellular telephones, smart phones, Personal Digital Assistants (PDAs), e-readers, gaming systems, music players, netbooks, wireless modems, laptop computers, tablet devices, etc.

The wireless communication device may include one or more image sensors, two or more image signal processors, a memory including instructions or modules for carrying out the process discussed above. The device may also have data, a processor loading instructions and/or data from memory, one or more communication interfaces, one or more input devices, one or more output devices such as a display device and a power source/interface. The wireless communication device may additionally include a transmitter and a receiver. The transmitter and receiver may be jointly referred to as a transceiver. The transceiver may be coupled to one or more antennas for transmitting and/or receiving wireless signals.

The wireless communication device may wirelessly connect to another electronic device (e.g., base station). A wireless communication device may alternatively be referred to as a mobile device, a mobile station, a subscriber station, a user equipment (UE), a remote station, an access terminal, a mobile terminal, a terminal, a user terminal, a subscriber unit, etc. Examples of wireless communication devices include laptop or desktop computers, cellular phones, smart phones, wireless modems, e-readers, tablet devices, gaming systems, etc. Wireless communication devices may operate in accordance with one or more industry standards such as the 3rd Generation Partnership Project (3GPP). Thus, the general term “wireless communication device” may include wireless communication devices described with varying nomenclatures according to industry standards (e.g., access terminal, user equipment (UE), remote terminal, etc.).

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer. Disk and disc, as used herein, includes compact disc (CD), laser disc, optical disc, digital versatile disc (DVD), floppy disk and Blu-ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It should be noted that the terms “couple,” “coupling,” “coupled” or other variations of the word couple as used herein may indicate either an indirect connection or a direct connection. For example, if a first component is “coupled” to a second component, the first component may be either indirectly connected to the second component or directly connected to the second component. As used herein, the term “plurality” denotes two or more. For example, a plurality of components indicates two or more components.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

In the foregoing description, specific details are given to provide a thorough understanding of the examples. However, it will be understood by one of ordinary skill in the art that the examples may be practiced without these specific details. For example, electrical components/devices may be shown in block diagrams in order not to obscure the examples in unnecessary detail. In other instances, such components, other structures and techniques may be shown in detail to further explain the examples.

The previous description of the disclosed implementations is provided to enable any person skilled in the art to make or use the present invention. Various modifications to these implementations will be readily apparent to those skilled in the art, and the generic principles defined herein may be applied to other implementations without departing from the spirit or scope of the invention. Thus, the present invention is not intended to be limited to the implementations shown herein but is to be accorded the widest scope consistent with the principles and novel features disclosed herein.

What is claimed is:

1. A sensing device, comprising:
a sensor array comprising a plurality of sensors, each sensor having a length dimension and a width dimension and configured to generate a signal responsive to radiation incident on the sensor; and
a filter array comprising a plurality of filters, the filter array disposed to filter light before it is incident on the sensor array, the filter array arranged relative to the sensor array so each of the plurality of sensors receives radiation propagating through at least one corresponding filter, each filter having a length dimension and a width dimension,
wherein a ratio of the length dimension of a filter to the length dimension of a corresponding sensor, a ratio of the width dimension of a filter to the width dimension of a corresponding sensor, or both, is a non-integer greater than 1.

2. The sensing device of claim 1, wherein the filter array comprises a repeated arrangement of filters, the repeated arrangement including:
a first filter having a first length and width dimension, configured to pass a first range of wavelengths;
a second filter having a second length and width dimension, configured to pass a second range of wavelengths;
a third filter having a third length and width dimension, configured to pass a third range of wavelengths; and
a fourth filter having a fourth length and width dimension, configured to pass any of the first, second, or third ranges of wavelengths.

3. The sensing device of claim 2, wherein the repeated arrangement of filters are arranged so that the first filter is disposed over a first sensor and over at least a portion of at least three other sensors adjacent to the first sensor.

4. The sensing device of claim 1, wherein the ratio of the length dimension of a filter to the length dimension of a corresponding sensor is a non-integer greater than 1.

5. The sensing device of claim 1, wherein a ratio of the width dimension of a filter to the width dimension of a corresponding sensor is a non-integer greater than 1.

6. The sensing device of claim 2, wherein at least some of the plurality of sensors are positioned relative to the filter elements to receive radiation filtered by no more than two of the first, second, third and fourth filters.

7. The sensing device of claim 2, wherein the length dimensions of the first filter, the second filter, the third filter, and the fourth filter are equal.

8. The sensing device of claim 2, wherein the width dimensions of the first filter, the second filter, the third filter, and the fourth filter are equal.

9. The sensing device of claim 2, wherein:
the first filter passes light wavelengths in a range of about 570 nm to about 750 nm;
the second filter passes light wavelengths in a range of about 450 nm to about 590 nm; and
the third filter passes light wavelengths in a range of about 380 nm to about 570 nm.

10. The sensing device of claim 1, wherein the filter array comprises a polymeric material.

11. The sensing device of claim 1, wherein the ratio of the length dimension of a filter and the length dimension of a corresponding sensor is between 1.0 and 2.0.

12. The sensing device of claim 1, wherein the ratio of the width dimension of a filter and the width dimension of a corresponding sensor is between 1.0 and 2.0.

13. A method, comprising:
filtering light propagating towards a sensor array with a filter array comprising a plurality of filters, the filter array positioned relative to the sensor array to filter the light before it is incident on the sensor array, each filter having a length dimension and a width dimension,
receiving the filtered light on the sensor array, the sensor array comprising a plurality of sensors each configured to generate a signal responsive to light incident on the sensor, the sensor array arranged relative to the filter array so each of the plurality of sensors receives light propagating through at least one filter corresponding to the sensor, each sensor having a length dimension and a width dimension, wherein a ratio of the length dimension of a filter to the length dimension of a corresponding sensor, a ratio of the width dimension of a filter to the width dimension of a corresponding sensor, or both, is a non-integer greater than 1.

14. The method of claim 13, wherein the filter array comprises a repeated arrangement of filters, the repeated arrangement including:
a first filter having a first length and width dimension, configured to pass a first range of wavelengths;
a second filter having a second length and width dimension, configured to pass a second range of wavelengths;
a third filter having a third length and width dimension, configured to pass a third range of wavelengths; and
a fourth filter having a fourth length and width dimension, configured to pass any of the first, second, or third ranges of wavelengths.

15. The method of claim 14, wherein the repeated arrangement of filters are arranged so that the first filter is disposed over a first sensor and over at least a portion of at least three other sensors adjacent to the first sensor.

16. The method of claim 13, wherein the ratio of the length dimension of a filter to the length dimension of a corresponding sensor is a non-integer greater than 1.

17. The method of claim 13, wherein a ratio of the width dimension of a filter to the width dimension of a corresponding sensor is a non-integer greater than 1.

18. The method of claim 14, wherein:
the first filter passes light wavelengths in a range of about 570 nm to about 750 nm;
the second filter passes light wavelengths in a range of about 450 nm to about 590 nm; and
the third filter passes light wavelengths in a range of about 380 nm to about 570 nm.

19. A sensing device, comprising:
a sensor array comprising a plurality of sensors, each sensor having a length dimension and a width dimension; and
means for filtering light propagating towards the sensor array, each of the means for filtering light positioned relative to the sensor array to filter the light before it is incident on one or more corresponding sensors, the means for filtering light each having a length dimension and a width dimension,
wherein a ratio of the length dimension of each of the means for filtering light to the length dimension of a corresponding sensor, a ratio of the width dimension of each means for filtering light to the width dimension of a corresponding sensor, or both, is a non-integer greater than 1.

20. The sensing device of claim 19, wherein the means for filtering light comprises an array of filters.

21. The sensing device of claim 19, wherein the means for filtering light comprises a repeated arrangement of filters, the repeated arrangement including:
a first filter having a first length dimension and a first width dimension, configured to pass a first range of wavelengths,
a second filter having a second length dimension and a second width dimension, configured to pass a second range of wavelengths,
a third filter having a third length dimension and a third width dimension, configured to pass a third range of wavelengths, and
a fourth filter having a fourth length dimension and a fourth width dimension, configured to pass any of the first range of wavelengths, the second range of wavelengths, or the third range of wavelengths.

22. The sensing device of claim 19, wherein the repeated arrangement of filters are arranged so that the first filter is disposed over a first sensor and over at least a portion of at least three other sensors adjacent to the first sensor.

23. The sensing device of claim 22, wherein at least some of the plurality of sensors are positioned relative to the filter elements to receive radiation filtered by no more than two of the first, second, third and fourth filters.

24. The sensing device of claim 22, wherein the length dimensions of the first filter, the second filter, the third filter, and the fourth filter are equal.

25. The sensing device of claim 22, wherein the width dimensions of the first filter, the second filter, the third filter, and the fourth filter are equal.

26. The sensing device of claim 22, wherein:
the first filter passes light wavelengths in a range of about 570 nm to about 750 nm;
the second filter passes light wavelengths in a range of about 450 nm to about 590 nm; and
the third filter passes light wavelengths in a range of about 380 nm to about 570 nm.

27. The sensor device of claim 19, wherein at least one of the filter length and width dimensions are sized relative to the sensor length and width dimensions, respectively, such that each of the filters have one or both of
a filter length dimension greater than the sensor length dimension and less than twice the sensor length dimension, and
a filter width dimension greater than the sensor width dimension and less than twice the sensor width dimension.

28. The sensing device of claim 19, wherein the ratio of the length dimension of a means for filtering light and the length dimension of a corresponding sensor is between 1.0 and 2.0.

29. The sensing device of claim 19, wherein the ratio of the width dimension of a means for filtering light and the width dimension of a corresponding sensor is between 1.0 and 2.0.

30. An apparatus, comprising:
a sensor array comprising a plurality of sensors, each of the plurality of sensors having a length dimension and a width dimension; and
a filter array comprising a plurality of filters, the filter array disposed adjacent to the sensor array such that light passing through the filter array is incident on the sensor array, each of the plurality of filters having a length dimension and a width dimension,
wherein at least one of the filter length and width dimensions are sized relative to the sensor length and width dimensions, respectively, such that the filters have one or both of
a filter length dimension greater than the sensor length dimension and less than twice the sensor length dimension, and
a filter width dimension greater than the sensor width dimension and less than twice the sensor width dimension.
